(19) United States
(12) Patent Application Publication
(10) Pub. No.: US 2024/0083804 A1
(43) Pub. Date: Mar. 14, 2024

(54) QUANTUM DOT-DOPED GLASS NANOCOMPOSITE AS A RADIATION COLOUR CONVERTER AND PRODUCTION METHOD THEREOF

(71) Applicants: YILDIZ TEKNIK UNIVERSITESI, Istanbul (TR); YILDIZ TEKNOLOJI TRANSFER OFISI ANONIM SIRKETI, Istanbul (TR)

(72) Inventors: Erdinc EROL, Istanbul (TR); Orhan KIBRISLI, Istanbul (TR); Ali Ercin ERSUNDU, Istanbul (TR); Miray CELIKBILEK ERSUNDU, Istanbul (TR)

(73) Assignees: YILDIZ TEKNIK UNIVERSITESI, Istanbul (TR); YILDIZ TEKNOLOJI TRANSFER OFISI ANONIM SIRKETI, Istanbul (TR)

(21) Appl. No.: 18/273,291

(22) PCT Filed: Jan. 19, 2022
(86) PCT No.: PCT/TR2022/050038

§ 371 Date: Jul. 20, 2023

(30) Foreign Application Priority Data
Jan. 20, 2021 (TR) 2021/00883

(51) Int. Cl. C03C 4/12; B82Y 20/00; B82Y 30/00; C03C 3/085; C03C 3/095; C03C 10/16; C09K 11/66

(52) U.S. Cl. CPC C03C 4/12; B82Y 20/00; B82Y 30/00; C03C 3/085; C03C 3/095; C03C 10/16; C09K 11/665

(57) ABSTRACT

A glass nanocomposite is doped with one or more of CdSe quantum dots and CsPbBr₃ quantum dots. A solid-state lighting system or a display panel backlight system including the glass nanocomposite as a radiation color converter is further provided. A solar cell including the glass nanocomposite as a luminescent solar concentrator is further provided. A method for obtaining said glass nanocomposite is further provided.

### CROSS REFERENCE TO THE RELATED APPLICATIONS

This application is the national phase entry of International Application No. PCT/TR2022/050038, filed on Jan. 19, 2022, which is based upon and claims priority to Turkish Patent Application No. 2021/00883, filed on Jan. 20, 2021, the entire contents of which are incorporated herein by reference.

### TECHNICAL FIELD

The present invention relates to nanocomposites in the fields of materials science, optics, photonics and chemistry. In particular, the present invention relates to glass nanocomposites containing a radiation color converter, and production method thereof.

### BACKGROUND

Existing commercial solid state white-radiating diodes (white LED or WLED) are formed by combining a blue-radiating LED chip and a Ce:YAG phosphor which absorbs some of the blue light and radiates yellow light, with silicone or organic binders, in which systems, white light is obtained by mixing blue and yellow light. Considering the visible region of the electromagnetic spectrum, the spectrum having only blue and yellow radiation is considered to be heterogeneous. Therefore, the capacity of WLEDs obtained by this method to display the colors in an environment to the observer is regarded insufficient in terms of NTSC (National Television System Committee) standard and CRI (Color Rendering Index) parameter. Meanwhile, scattering losses due to the refractive index difference between silicon or organic binder and phosphorus, low chemical and thermal stability of phosphorus material (Ce:YAG), degradation of the binder under UV light and/or the heat generated by the LED chip in time are problems concerning commercial WLEDs, and accordingly there is a need to improve WLEDs.

Quantum dots are nanosized (1-20 mm), semiconductive crystal materials that are hotspot for their unique properties such as high absorption cross-section, size-dependent band gap energy, adjustable radiation wavelength, and high photoluminescence quantum efficiency. With their superior properties, quantum dots have a high potential for use in radiation color converter applications such as solid state lighting, luminescent solar concentrator and display backlight. However, due to their strong ionic structure and high surface energy, quantum dots degrade when exposed to polar solvents such as water, to high temperature and high radiation intensity.

In order to improve the radiation color properties of the commercially used WLEDs, studies have been conducted to obtain a more homogeneous radiation spectrum by combining different materials that radiate separately red and green colors with blue LED chips. Most of these studies are based on the principle of depositing colloidal (wet chemistry, solution based) quantum dots on various substrate materials in the form of thin films. Also, various techniques have been developed, such as the production of quantum dots in organic or inorganic matrices such as polymers by means of surface modification and/or encapsulation. Although improvements are made with these methods in terms of radiation properties of quantum dots, the stability and degradation problems have not been solved at a desired level.

These colloidal based, quantum dot containing materials that is suitable to be prepared in the form of thin films are generally only stable at temperatures up to 200° C. Therefore, it can be said that their thermal resistance and stability are relatively low. Since colloidal based, quantum dot containing materials that is suitable to be prepared in the form of thin films are highly sensitive to moisture and oxygen, they start to degrade even in short time contacts in the order of minutes or hours; therefore, it can be said that the chemical stability thereof is relatively low. In addition, it can be said that the mechanical strength of colloidal based, quantum dot containing materials which can be prepared in thin film form is low. Quantum dots synthesized colloidally can also be embedded in various polymer matrices whose thermal and mechanical strength is considerably lower than inorganic glasses.

In order to combine the blue light originating from an LED chip with other primary colors (red, green) or the mixtures thereof, different glass layers doped with different quantum dots are disposed on the LED chip so as to obtain the white light. However, using more than one glass layer on the LED chip in these designs causes the light to be refracted as it passes through the layers, resulting in scattering losses. Therefore, obtaining a homogeneous radiation spectrum by using a single glass layer is important in terms of increasing radiation intensity.

In order to achieve superior radiation properties, the red, green and blue radiation bands of the white light components must cover a large part of the visible region. In the studies to obtain white light using lanthanide ions, the full width at half maximum (in short: FWEIM) of rare earth ions is narrow, and the fixed central wavelength values prevent a large part of the visible region of the electromagnetic spectrum to be covered. At this point, the radiation bands of quantum dots with broad and adjustable wavelengths make it possible to obtain radiation bands that cover the entire visible region.

In devices developed to produce white light using a blue LED chip and perovskite quantum dots (CsPbBr₃, green radiation), the red radiation is obtained by using CsPbI₃ PQDs (see FIG. 1) with low quantum efficiency, lanthanide ions (see FIG. 2) with narrow FWHM and fixed central wavelength values such as Eu³⁺, or phosphorus materials with low chemical and thermal resistance such as Eu²⁺:CaAlSiN₃ (see FIG. 3). The white light produced using these materials cannot meet the properties expected from an ideal white light source.

### OBJECTS OF THE INVENTION

The main object of the invention is to eliminate the problems encountered in the prior art. Another object of the invention is to prevent the degradation of quantum dots and to ensure that the radiation properties can be preserved for a long period time.

Another object of the invention is to provide a nanocomposite structure in which improved radiation properties and a high quantum dot strength are provided in a radiation color converter.

Still another object of the invention is to provide a method for obtaining such a nanocomposite structure.

### SUMMARY

The present invention provides a glass nanocomposite doped with one or more CsPbBr₃ quantum dots and one or more CdSe quantum dots, and a method for obtaining same.

The nanocomposite of the invention is suitable for use as a radiation color converter in a solid state lighting system or a display panel backlight system, or as a luminescent solar concentrator in a solar cell.

Therefore, the present invention also provides a solid state lighting system, or a display panel backlight system, comprising the inventive glass nanocomposite as a radiation color converter, and a solar cell comprising the inventive glass nanocomposite as a luminescent solar concentrator.

### BRIEF DESCRIPTION OF THE DRAWINGS

The present invention is exemplified below with reference to the accompanying figures for better understanding thereof, which examples are only illustrative of the embodiments of the present invention and are not limiting other embodiments and general functions providing the solution of the technical problem.

FIG. 1 is a schematic view of a next generation comparative WLED design that is suitable to be used for the generation of white light.

FIG. 2 is a schematic view of another next generation comparative WLED design that is suitable to be used for the generation of white light.

FIG. 3 is a schematic view of another next generation comparative WLED design that is suitable to be used for the generation of white light.

FIG. 4 is a schematic view of a WLED design presented within the scope of the present invention, for use in the generation of white light.

FIG. 5 is a schematic cross-sectional view of the inventive quantum dot doped glass nanocomposite included in a solid state lighting system, for example together with an LED chip.

FIG. 6 is a photoluminescence (PL) graph of the quantum dot doped glass nanocomposite presented within the scope of the present invention. Here, the stimulative wavelength is 365 nm.

### DETAILED DESCRIPTION OF THE EMBODIMENTS

Hereinafter, the present invention is described in detail, based on the drawings, whose brief description given above. The list of reference symbols used in the figures is as follows;
1 glass nanocomposite of the invention
2 CdSe quantum dots
3 CsPbBr₃ quantum dots
5 characteristic photoluminescence peak of the CsPbBr₃ quantum dot
6 characteristic photoluminescence peak of the CdSe quantum dot
10 light source, such as LED chip, such as blue LED chip or UV LED chip
11 first glass nanocomposite layer doped with a PQD such as CsPbI₃ that has low red radiation quantum efficiency
12 second glass nanocomposite layer doped with green-radiating (CsPbBr₃) PQD
13 glass nanocomposite layer doped with a lanthanide such as red-radiating Eu³⁺ with narrow FWHM and fixed central wavelength values, and with CsPbBr₃ PQD
14 first layer consisting of red-radiating Eu²⁺:CaAlSiN₃-based phosphorus or red-radiating Eu²⁺:CaAlSiN₃-based phosphorus
B blue light
G green radiation
R red radiation
W white light
L thickness

With the present invention, a nanocomposite is developed in order to eliminate the disadvantages mentioned in the background art section.

In order to prevent the degradation of quantum dots and to preserve their exceptional radiation properties for a long period of time, it is appropriate to encapsulate them in a thermally, chemically and mechanically stable material. In this context, glass stands out as the encapsulation material with the highest potential for their high optical transmittance, ease of production, 100% recyclability and exceptional thermal, chemical and mechanical resistance. Since the synthesis of quantum dots directly in glass matrices results in their zero contact with the outside environment and passivation of their surfaces, their radiation properties can be preserved for a long period time.

Glass nanocomposites that are to be obtained from the synthesis of quantum dots in suitable glass matrices will meet such shortcomings of solar cells, which degrade under UV light and cannot produce energy with UV light, especially WLED solid state lighting systems, and the expectation of obtaining a wide color gamut in display panels, with their thermal and chemical stabilities and the radiation color converter properties, and will allow the development of new commercial products that can use radiation color converters.

### Comparative Example 1

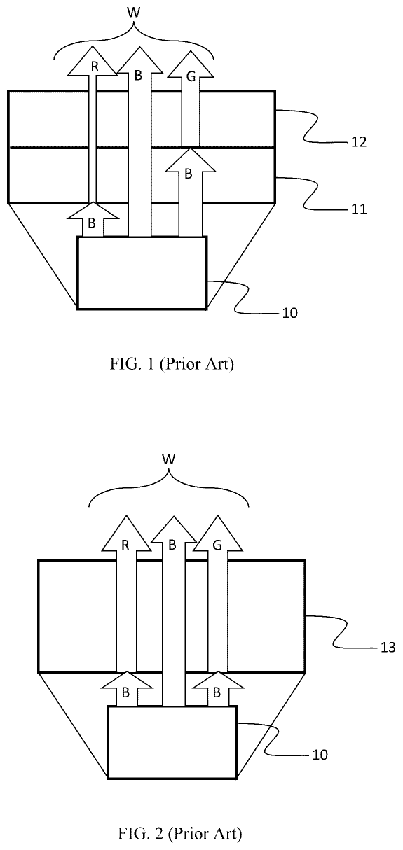

FIG. 1 shows a device comprising a light source (10) (e.g., a blue LED chip) emitting blue light (B) and developed to produce white light by the effect of doped nanocomposite.

The device includes a first glass nanocomposite layer (11) doped with perovskite quantum dots (in short: PQD) such as CsPbI₃, which have low red radiation (R) quantum efficiency, as a radiation color converter, and also a second glass nanocomposite layer (12) doped with green radiating (G) (CsPbBr₃) PQD. Thus, as the blue rays (B) originating from blue radiation pass through the nanocomposite layers, PQDs in nanocomposite layers generate red radiation (R) and green radiation (G) so that white light (W) (or white color) is obtained.

The low efficiency of red radiation (R) due to CsPbI₃ doping is represented with a thin arrow.

### Comparative Example 2

FIG. 2 shows a device comprising a blue LED chip (10) emitting blue light (B) and developed to produce white light by the effect of a doped nanocomposite.

The device includes a glass nanocomposite layer (13) doped with a red (R) radiating lanthanide such as Eu³⁺, as a radiation color converter, and green (G) radiating (CsPbBr₃) PQD. Thus, as the blue rays or blue light (B) pass through the nanocomposite, Eu³⁺ ions in nanocomposite generate a red radiation (R) and PQDs generate a green radiation (G) so that white light (W) (or white color) is obtained.

Here, the absorption cross-sectional area, quantum efficiency and FWHM values of Eu³⁺ ions used for red radiation are low.

### Comparative Example 3

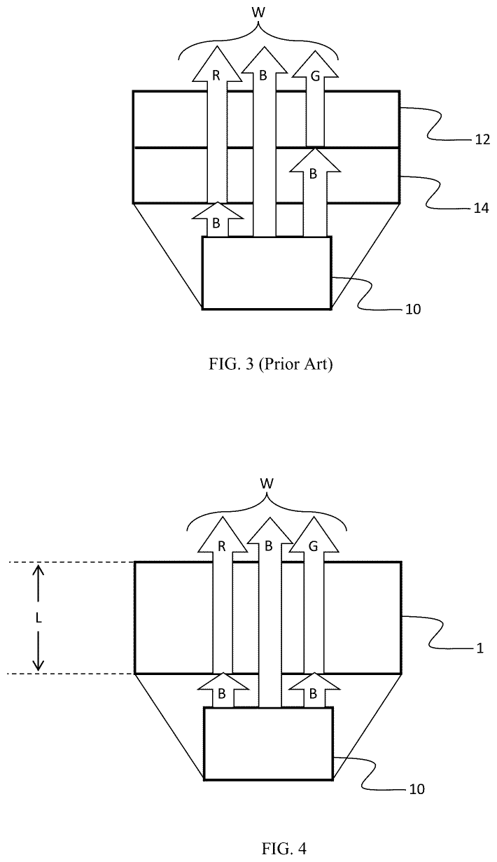

FIG. 3 shows a device comprising a blue LED chip emitting blue light (B), which is also developed to produce white light (W) by the effect of a first layer and a second being doped nanocomposite.

The device includes a first layer (14) consisting of red radiating Eu²⁺:CaAlSiN₃-based phosphorus or red radiating Eu²⁺:CaAlSiN₃-based phosphorus, as a radiation color converter, and also a second glass nanocomposite layer (12) doped with green radiating (G) (CsPbBr₃) PQD. Thus, as the blue rays (B) pass through the first layer (14) and the second layer (12), said first and second layers separately emit red radiation (R) and green radiation (G) so that white light (W) (or white color) is obtained.

The red radiating phosphor material used herein has low chemical and thermal resistance.

Example 4, the effect of the nanocomposite of the invention:

FIG. 4 shows a device comprising a light source (10) (e.g., a blue LED chip) emitting blue ray (B) and developed to produce white light by the effect of doped nanocomposite according to the present invention.

The device includes a glass nanocomposite layer (i.e., the inventive glass nanocomposite (1) doped with quantum dots of CdSe and CsPbBr₃) doped with green (G) radiating CsPbBr₃ (cesium lead bromide) perovskite quantum dots (in short: PQD), and red (R) radiating CdSe (cadmium selenide) QD, as a radiation color converter. Thus, as the blue rays (B) originating from the blue radiation pass through the nanocomposite layer (1), CdSe quantum dots (2) in the nanocomposite layer emit red radiation (R) and CsPbBr₃ (perovskite) quantum dots (3) emit green radiation (G) so that white light (W) (or white color) is obtained.

With the CdSe doping, the red radiation (R) efficiency is high.

In light of the above, a glass nanocomposite (1) doped with CdSe quantum dots (2) and CsPbBr₃ quantum dots (3) is presented in the present invention. With the CdSe quantum dots (2), red and preferably additional yellow radiation is achieved. With the CsPbBr₃ quantum dots (3), green radiation is achieved. With the improvement of the present invention, silicate glass nanocomposite (1), doped with green radiating CsPbBr₃ quantum dots (3) as well as red and yellow radiating CdSe quantum dots (2) with high FWHM, have high thermal, chemical and mechanical strength. In this context, a radiation color converter having ideal properties is proposed by synthesizing CdSe quantum dots (2) and CsPbBr₃ quantum dots (3), which radiate in red and green regions with high efficiency, in a single glass matrix.

The inventive glass nanocomposite (1) radiates red light (R) and green light (G) with blue light emitted from a light source (10) (e.g., an LED chip) coupled with it, and radiation of all colors are combined to provide the radiation color properties expected from an ideal white light source.

The quantum dot glass nanocomposite (1) which is the subject of the present invention has at least the following advantages compared to colloidal-based materials containing quantum dots, which can be prepared in thin film form:
After repeated heating-cooling cycles up to 400° C., it preserves its initial original radiation properties, therefore said nanocomposite provides a high thermal stability.
Even when it is immersed in water for more than 60 days no adverse effects on the radiation properties were observed, thus said nanocomposite has a high chemical stability.
Quantum dot-doped glass nanocomposites have very high mechanical strength compared to colloidal-based thin films and quantum dot-doped polymers.
CdSe quantum dots (2) and CsPbBr₃ quantum dots (3) are sensitive to different stimulation wavelengths. Therefore, said nanocomposite allows to adjust the radiation color to green, red, yellow and orange depending on the stimulation wavelength, which can be in the range of 345 nm-405 nm.

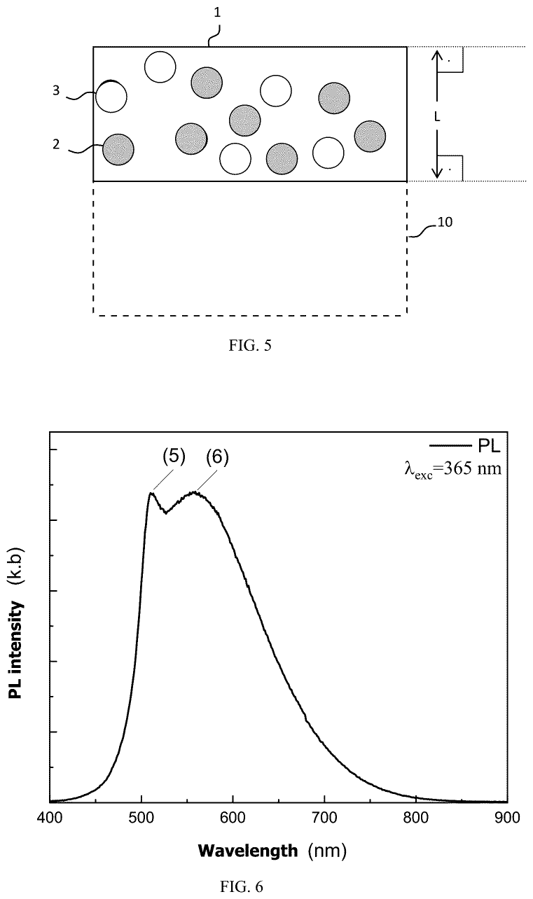

The glass nanocomposite (1) which is the subject of the invention containing CdSe quantum dots (2) and CsPbBr₃ quantum dots (3) simultaneously is schematically shown in FIG. 5. In FIG. 5, dashed lines are used to symbolize that the glass nanocomposite (1) of the invention can be coupled with, for example, a light source (10).

In addition to its superior and adjustable radiation properties, the glass nanocomposite (1) of the invention, due to its thermal, chemical and mechanical resistance, has the potential for use as a radiation color converter in durable solid state lighting devices, as illustrated in FIG. 4 and FIG. 5, or solar cells (not shown), or display panel backlight system (not shown) technologies.

The present invention also provides a method for obtaining the glass nanocomposite (1) of the invention.

The method includes the following steps:
a) preparing a blend of glass,
b) melting the glass blend prepared in step a,
c) obtaining a molded sample by pouring the glass blend melted in step b into a mold,
d) annealing of the molded sample obtained in step c, thus obtaining an annealed sample,
e) controlled crystallization of CdSe and CsPbBr₃ quantum dots by heat treatment of the annealed sample obtained in step d at a temperature above the glass transition temperature, thereby obtaining a glass nanocomposite containing quantum dots,
f) controlled cooling of the glass nanocomposite obtained in step e.

The glass blend in step a of the method is prepared to contain the following components, with the total mole percent concentrations of each constituent component being 100: SiO₂ in the range of 40% to 60% by mole; alkali metal oxide in the range of 15% to 25% by mole; Al₂O₃ in the range of 2% to 10% by mole; ZnO in the range of 5% to 15% by mole, CsBr in the range of 3% to 7% by mole, PbBr₂ in the range of 6% to 14% by mole, as well as
CdO in the range of 0.5% to 5% by mole and ZnSe in the range of 0.5% to 5% by mole, or
Cdse in the range of 0.5% to 5% by mole.

Said alkali metal oxide may be one or more selected from Li₂O, Na₂O, and K₂O.

As can be understood, the glass blend may contain CdO and ZnSe together, and as a result of the chemical reaction that will take place between them during the performance of the method, CdSe (thus CdSe quantum dots (2)) is formed as a product. Alternatively, CdSe can be directly included in the glass blend and does not experience chemical transformation while the method is performed.

Therefore, the mole percent composition of the glass blend can be formed by considering the components shown in either Table 1 and Table 2 below, and the mole percent concentrations corresponding to said components. Here, the term mole percent concentration is the proportion of each component in the total number of moles of components in the glass blend.

TABLE 1
The first alternative for the components in the glass blend
in step a of the method and their percent concentration
based on the total number of moles in the glass blend.

| | Concentration of the component in the glass |
|---|---|
| Component | blend (% mole) |
| SiO₂ | in the range of 40% to 60% |
| alkali metal oxide | in the range of 15% to 25% |
| Al₂O₃ | in the range of 2% to 10% |
| ZnO | in the range of 5% to 15% |
| CsBr | in the range of 3% to 7% |
| PbBr₂ | in the range of 6% to 14% |
| CdO | in the range of 0.5% to 5% |
| ZnSe | in the range of 0.5% to 5% |

TABLE 2
The second alternative for the components in the glass blend
in step a of the method and their percent concentration
based on the total number of moles in the glass blend.

| | Concentration of the component in the glass |
|---|---|
| Component | blend (% mole) |
| SiO₂ | in the range of 40% to 60% |
| alkali metal oxide | in the range of 15% to 25% |
| Al₂O₃ | in the range of 2% to 10% |
| ZnO | in the range of 5% to 15% |
| CsBr | in the range of 3% to 7% |
| PbBr₂ | in the range of 6% to 14% |
| CdSe | in the range of 0.5% and 5% |

In the melting process in step b of the method, the glass blend can be raised to a temperature value preferably in the range of 1000° C. to 1450° C. Said temperature may be referred to as the melting temperature. The glass blend can be placed in a pot for the melting process, said pot may be made from a material resistant to temperatures above 1000° C., such as quartz, alumina or platinum.

Preferably, in step c of the method, the mold may be preheated to a temperature in the range of 350° C. to 550° C. prior to the casting process. The temperature preferred for preheating may be referred to as the preheating temperature. The mold may be formed from a metallic material such as stainless steel, brass or copper.

The annealing in step d of the method is preferably carried out for a period of 1 to 5 hours. Said period in which the annealing process is carried out may be referred to as an annealing period. The glass transition temperature of the glass blend prepared according to the description in step a of the method is expected to be 20° C. to 100° C. higher than a temperature in the range 350° C. to 550° C. In this context, the annealing process may preferably be performed at a temperature value below 20° C. to 100° C. of the glass transition temperature of the molded sample, i.e., for example in the range of 350° C. to 550° C. The temperature in the annealing process may be referred to as an annealing temperature. The purpose of the annealing process is to eliminate internal stress resulting from rapid cooling.

The heat treatment in step e of the method may, for example, have a single stage or for example two stages or more. The heat treatment in step e of the method may preferably be carried out for a period in the range of 1 to 72 hours. Said period in which the heat treatment is carried out may be referred to as a heat treatment period. The heat treatment in step e of the method may preferably be carried out at a temperature in the range of 400° C. to 600° C.; therefore, in this case, the temperature of the heat treatment corresponds to a temperature value above the glass transition temperature. The temperature value during heat treatment may be referred to as a heat treatment temperature.

The controlled cooling in step f of the method may preferably be continued to a temperature corresponding to a temperature below 30° C., more preferably to a temperature corresponding to room temperature (20° C.). The temperature reached at the end of the said controlled cooling may be referred to as an operating temperature. Preferably, step f of the method may be followed by step g below:
g) preparing at least one surface of the sample cooled in step fat optical quality.

Here, the process of preparing the surface at optical quality may include any of the methods applied and known in the field of optics. The process of preparing at optical quality may be carried out by means of grinding and polishing, and may, for example, correspond to the reduction of the average roughness of the surface to 1 micrometer or less.

Preferably, prior to step g of the method, a thickness (L) of the sample cooled in step f is brought to a value in the range of 0.1 to 2 mm. Bringing the thickness (L) of the sample to a value in the range of 0.1 to 2 mm may be achieved, for example, by known sample preparation techniques. Sample preparation techniques include, for example, any of the methods of grinding, cutting, mechanical or chemical etching. Here, the term thickness (L) can be considered to correspond to a length of a light transmittance path between a first surface and a second surface of the glass nanocomposite of the invention. Preferably said term of thickness (L) may be considered to correspond to a length of a light transmittance path perpendicular to at least one of these surfaces, i.e., in the perpendicular direction (see FIG. 4). More preferably, said term of thickness (L) may be considered to correspond to a length of a light transmittance path that is perpendicular to both of these surfaces, i.e., in the perpendicular direction (see FIG. 5). Such thickness (L) value may be considered as a minimum value at which the light transmittance path is the shortest.

With the method of the invention, a glass nanocomposite (1) is obtained which comprises CdSe quantum dots (2) and CsPbBr₃ quantum dots (3) dispersed homogenously in the glass matrix, with a quantum efficiency above 10%. The diameters of the resulting quantum dots (2 and 3) can be in the range of 1.5 nm to 10 nm.

The present invention also proposes the use of the inventive glass nanocomposite (1) doped with CdSe quantum dot (2) and CsPbBr₃ quantum dot (3) in solid state lighting applications. A solid state lighting application suitable for this specification may for example be a WLED or a white LED. In the context of said use, the glass nanocomposite (1) of the invention is disposed on a light source (10) (e.g., a UV light source, blue light source or violet light source), in order to allow CdSe quantum dots (2) and CsPbBr₃ quantum dots (3) to radiate red (R) (red-yellow) and green radiation (G), respectively. White color (W) (or white light) is obtained as a mixture of all the resulting radiations (R+G+B). Therefore, the present invention also provides a solid state lighting system containing the inventive glass nanocomposite (1) as a radiation color converter.

The present invention also proposes the use of the inventive glass nanocomposite (1) in a display panel backlight. A wide color gamut (Rec. 2020) is needed for display panel backlights. A wide color gamut that is suitable to be used in display panel backlights can be obtained by simply adjusting the ratios of CsPbBr₃ and CdSe in the glass nanocomposite of the invention and the current, voltage and radiation wavelength values of the light source (10). Accordingly, the present invention also provides a display panel backlight system (not shown) comprising the glass nanocomposite (1) of the invention as a radiation color converter.

The present invention also proposes the use of the inventive glass nanocomposite (1) as a luminescent solar concentrator (in short: LSC) in solar cells. Commercially used Si solar cells are degraded by the effect of UV light and cannot produce energy by absorbing UV light. CdSe quantum dots (2) and CsPbBr₃ quantum dots (3) can absorb UV light and radiate in the visible region, i.e., in the region where commercially used solar cells are sensitive. When the glass nanocomposites of the invention are combined with solar cells by selecting the appropriate geometry, they can increase the performance of the solar cells and extend their lifetime. Therefore, the present invention also provides a solar cell (not shown) comprising the glass nanocomposite (1) of the invention as a luminescent solar concentrator.

What is claimed is:

1. A glass nanocomposite, wherein the glass nanocomposite is doped with one or more CdSe quantum dots and one or more CsPbBr₃ quantum dots.

2. The glass nanocomposite according to claim 1, wherein the one or more CdSe quantum dots and the one or more CsPbBr₃ quantum dots have a radius in a range of 1.5 nm to 10 nm.

3. A solid state lighting system, comprising the glass nanocomposite according to claim 1.

4. A display panel backlight system, comprising the glass nanocomposite according to claim 1.

5. A solar cell, comprising the glass nanocomposite according to claim 1 as a luminescent solar concentrator.

6. A method for obtaining a glass nanocomposite doped with one or more CdSe quantum dots and one or more CsPbBr₃ quantum dots comprising the following steps:
step a: preparing a glass blend to contain the following components, with a total of mole percent concentrations of each component being 100:
SiO₂ in a range of 40% to 60% by mole; one or more alkali metal oxides selected from Li₂O, Na₂O and K₂O with a total range of 15% to 25% by mole; Al₂O₃ in a range of 2% to 10% by mole; ZnO in a range of 5% to 15% by mole, CsBr in a range of 3% to 7% by mole, PbBr₂ in a range of 6% to 14% by mole; and
CdO in a range of 0.5% to 5% by mole and ZnSe in a range of 0.5% to 5% by mole,
or
CdSe in a range of 0.5% to 5% by mole;
step b: melting the glass blend prepared in step a,
step c: obtaining a molded sample by pouring the glass blend melted in step b into a mold,
step d: performing annealing on the molded sample obtained in step c to obtain an annealed sample,
step e: performing controlled crystallization of on CdSe quantum dots and CsPbBr₃ quantum dots by heat treatment of the annealed sample obtained in step d at a temperature above a glass transition temperature to obtain a glass nanocomposite sample containing quantum dots, and
step f: performing controlled cooling on the glass nanocomposite obtained in step e.

7. The method according to claim 6, wherein in a melting process in step b, the glass blend is raised to a temperature value in a range of 1000° C. to 1450° C.

8. The method according to claim 6, wherein in step c, prior to a casting process, the mold is preheated to a temperature in a range of 350° C. to 550° C.

9. The method according to claim 6, wherein in step d, an annealing process is carried out for a period of 1 hour to 5 hours.

10. The method according to claim 6, wherein during an annealing process in step d, a temperature value is in a range of 350° C. to 550° C.

11. The method according to claim 6, wherein a heat treatment in step e is carried out for a period of 1 hour to 72 hours.

12. The method according to claim 6, wherein a heat treatment in step e is carried out at a temperature in a range of 400° C. to 600° C.

13. The method according to claim 6, wherein the controlled cooling in step f is continued until a temperature below 30° C. is reached.

14. The method according to claim 6, wherein the controlled cooling in step f is continued until a temperature of 20° C. is reached.

15. The method according to claim 6, comprising the following step after step f:
g) preparing at least one surface of the sample cooled in step f such that the an average roughness of the sample is equal to or less than 1 micrometer.

16. The method according to claim 15, comprising, before step g, bringing a thickness of the sample cooled in step f to a value in a range of 0.1 mm to 2 mm.

17. The solid state lighting system according to claim 3, wherein in the glass nanocomposite, the one or more CdSe quantum dots and the one or more CsPbBr₃ quantum dots have a radius in a range of 1.5 nm to 10 nm.

18. The display panel backlight system according to claim 4, wherein in the glass nanocomposite, the one or more CdSe quantum dots and the one or more CsPbBr₃ quantum dots have a radius in a range of 1.5 nm to 10 nm.

19. The solar cell according to claim 5, wherein in the glass nanocomposite, the one or more CdSe quantum dots and the one or more CsPbBr₃ quantum dots have a radius in a range of 1.5 nm to 10 nm.

20. The method according to claim 7, wherein in step c, prior to a casting process, the mold is preheated to a temperature in a range of 350° C. to 550° C.
